(19) United States
(12) Patent Application Publication
(10) Pub. No.: US 2016/0141293 A1
(43) Pub. Date: May 19, 2016

(54) SEMICONDUCTOR MEMORY DEVICE AND METHOD FOR MANUFACTURING SAME

(71) Applicant: KABUSHIKI KAISHA TOSHIBA, Minato-ku (JP)

(72) Inventors: Jun MURAKAMI, Yokkaichi (JP); Kimitoshi OKANO, Yokkaichi (JP); Koichi MATSUNO, Mie (JP)

(73) Assignee: KABUSHIKI KAISHA TOSHIBA, Minato-ku (JP)

(21) Appl. No.: 14/728,031

(22) Filed: Jun. 2, 2015

Related U.S. Application Data
(60) Provisional application No. 62/081,774, filed on Nov. 19, 2014.

(51) Int. Cl. H01L 27/115; H01L 21/28

(52) U.S. Cl. CPC H01L 27/1157; H01L 21/28273

(57) ABSTRACT

According to one embodiment, a semiconductor memory device includes a memory cell; and a peripheral transistor. The memory cell includes a first channel, a first insulating film provided on the first channel, a charge storage film provided on the first insulating film, a second insulating film provided on the charge storage film, a first semiconductor film provided on the second insulating film, and a first electrode film provided on the first semiconductor film and containing a metal. The peripheral transistor includes a second channel, a third insulating film provided on the second channel, a second semiconductor film provided on the third insulating film, a fourth insulating film provided on the second semiconductor film, a third semiconductor film provided on the second semiconductor film and a side surface of the fourth insulating film, and a second electrode film.

This application is based upon and claims the benefit of priority from U.S. Provisional Patent Application 62/081,774 field on Nov. 19, 2014; the entire contents of which are incorporated herein by reference.

### FIELD

Embodiments described herein relate generally to a semiconductor memory device and a method for manufacturing same.

### BACKGROUND

A polyside or a polymetal is, for example, used as a gate electrode of a transistor in a memory cell and a peripheral circuit in a NAND flash memory. In a structure using the gate material described above, improvement in characteristics of not only the memory cell but also the peripheral circuit is required.

### BRIEF DESCRIPTION OF THE DRAWINGS

FIG. 1A is a schematic plan view illustrating a plan layout of a memory cell region of a semiconductor memory device of an embodiment, and FIG. 1B is a schematic plan view illustrating a plan layout of a peripheral circuit of the semiconductor memory device of the embodiment;

FIG. 2A to FIG. 2D are schematic cross-sectional views of the semiconductor memory device of the embodiment;

FIG. 3 to FIG. 7D are schematic cross-sectional views showing a method for manufacturing the semiconductor memory device of the embodiment;

FIG. 8A and FIG. 8B are schematic cross-sectional views of the semiconductor memory device of other embodiment;

FIG. 9A is a concentration profile diagram of the impurity contained in the structure and FIG. 9B is an energy band diagram; and

FIG. 10A to FIG. 12B are schematic cross-sectional views showing a method for manufacturing the semiconductor memory device of the other embodiment.

### DETAILED DESCRIPTION

According to one embodiment, a semiconductor memory device includes a memory cell; and a peripheral transistor. The memory cell includes a first channel, a first insulating film provided on the first channel, a charge storage film provided on the first insulating film, a second insulating film provided on the charge storage film, a first semiconductor film provided on the second insulating film, and a first electrode film provided on the first semiconductor film and containing a metal. The peripheral transistor includes a second channel, a third insulating film provided on the second channel, a second semiconductor film provided on the third insulating film, a fourth insulating film provided on the second semiconductor film, a third semiconductor film provided on the second semiconductor film and a side surface of the fourth insulating film, and a second electrode film provided on the fourth insulating film without the third insulating film between the second electrode film and the fourth insulating film, provided on the second semiconductor film in contact with the second semiconductor film, and including a metal.

Embodiments will be described below with reference to the drawings. In the drawings, the same elements have the same reference characters. Further, the following embodiments will be described assuming that a first conductivity type is n-type and a second conductivity type is p-type, and the embodiment can also be implemented assuming that the first conductivity type is p type and the second conductivity type is n type.

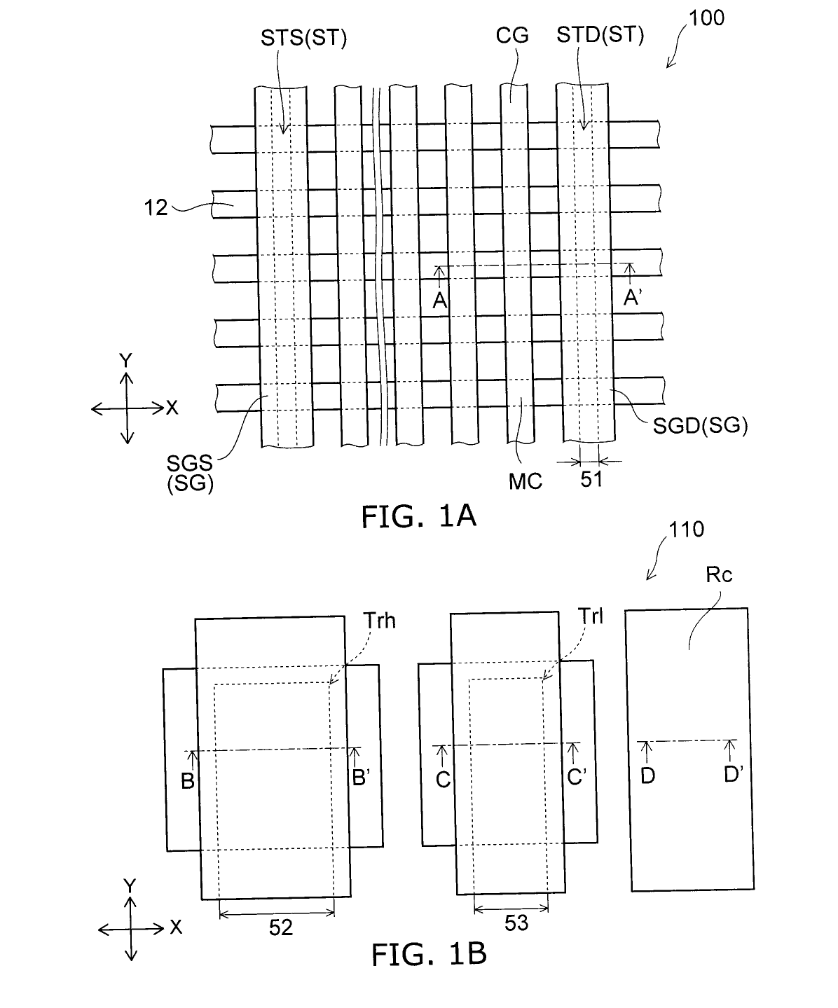

FIG. 1A is a schematic plan view illustrating a plan layout of a memory cell region of a semiconductor memory device of an embodiment, and FIG. 1B is a schematic plan view illustrating a plan layout of a peripheral circuit (control circuit) of the semiconductor memory device of the embodiment.

As shown in FIG. 1A and FIG. 1B, the semiconductor memory device includes memory cells MC, selection transistors ST (drain-side selection transistors STD, source-side selection transistors STS), and transistors used in a peripheral circuit (hereinafter referred to as peripheral transistors). The peripheral transistors include a high-voltage peripheral transistor Trh and a low-voltage peripheral transistor Trl. The selection transistors ST include selection gates SG (drain-side selection gate SGD, source-side selection gate SGS).

As shown in FIG. 1A, channel regions 12, control gates CG, and the selection gates SG are provided in a memory cell region 100. The channel regions 12 extend in a first direction (X-direction), and the plurality of channel regions 12 are separated from each other in a second direction (Y-direction) that intersect the X-direction (perpendicular to X-direction, for example).

The channel regions 12 adjacent to each other in the Y-direction are separated from each other by an STI (shallow trench isolation) structure. That is, a trench is provided between the channel regions 12 adjacent to each other in the Y-direction, and an insulating film, made, for example, of a silicon oxide is buried in the trench.

The control gates CG extend in the Y-direction, and the plurality of control gates CG are separated from each other in the X-direction. An insulating film is provided between the control gates CG adjacent to each other in the X-direction, as in the case of the channel regions 12.

The memory cells MC are provided on the channel regions 12 and in the positions where the channel regions 12 intersect the control gates CG. The plurality of memory cells MC are separated from each other in an XY plane.

The selection gates SG are provided on both outsides of a plurality of columns formed of the memory cells MC and arranged in the X-direction. The selection gates SG extend in the Y-direction. The selection gates SG are wider, for example, than the control gates CG in the X-direction.

The selection gates SG have a source-side selection gate SGS and a drain-side selection gate SGD. The source-side selection gate SGS is provided on one side of the plurality of columns formed of the memory cells MC and arranged in the X-direction, and the drain-side selection gate SGD is provided on the other side of the plurality of columns.

The selection transistors ST (source-side selection transistors STS, drain-side selection transistors STD) are provided on the channel regions 12 and in the positions where the channel regions 12 intersect the selection gates SG.

Each of the source-side selection transistors STS, the corresponding drain-side selection transistor STD, and the plurality of memory cells MC between the source-side selection transistor STS and the drain-side selection transistor STD are connected in series by the corresponding channel region 12 to form a memory string (NAND string). Each of the channel regions 12 includes first channels 12a for the memory cells MC, second channels 12b for the peripheral transistors Trh and Trl, and third channels 12c for the selection transistors ST, as will be described later.

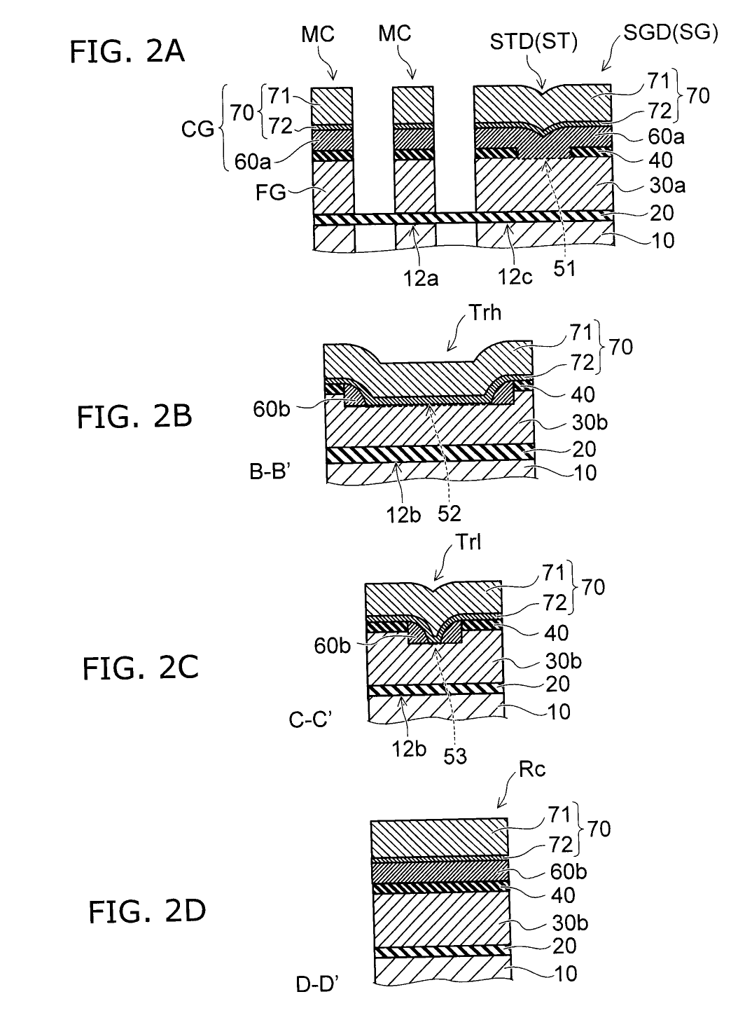

FIG. 2A is a schematic cross-sectional view of some of the memory cells MC and one of the drain-side selection transistors STD taken along the line A-A′ in FIG. 1A. An insulating film that is not shown is provided between the drain-side selection transistor STD and the memory cell MC adjacent thereto. The source-side selection transistor STS have the same structure as that of the drain-side selection transistors STD and will not therefore be described.

The channels 12a and 12c are provided on a surface of a substrate 10, as shown in FIG. 2A. The first channels 12a are provided on the surface of the substrate 10 where the memory cells MC are present, and the third channels 12c are provided on the surface of the substrate 10 where the drain-side selection gates SGD are present.

The substrate 10 is, for example, so provided that it continuously extends in an XY plane in FIG. 1A and FIG. 1B. The memory cells MC, the selection transistors ST, the high-voltage peripheral transistor Trh, and the low-voltage peripheral transistor Trl are therefore provided on the same substrate 10 and integrated with each other into a single chip.

A gate insulating film 20 (or tunnel insulating film, first insulating film) is provided on the first channels 12a for the memory cells MC. A silicon oxide film or any other suitable film is used as the gate insulating film 20.

A floating gate FG (charge storage film) is provided on the gate insulating film 20. The floating gate FG is made, for example, of a p-type (second-conductivity-type) semiconductor. The floating gate FG is made, for example, of polysilicon into which a p-type impurity (boron, for example) is doped.

An interlayer insulating film 40 (second insulating film) is provided on the floating gate FG. The interlayer insulating film 40 is made, for example, of a material having relative permittivity higher than that of the gate insulating film 20. The interlayer insulating film 40 is formed, for example, of an ONO (oxide-nitride-oxide) film, an NONON (nitride-oxide-nitride-oxide-nitride) film, or a film produced by replacing each of the nitride films in the ONO film or the NONON film with an insulating film having a high dielectric characteristic.

The control gates CG are provided on the interlayer insulating film 40. Each of the control gates CG has a semiconductor film 60a and an electrode film 70.

The semiconductor film 60a (first semiconductor film) is provided on the interlayer insulating film 40. The semiconductor film 60a is made of a p-type semiconductor, as the floating gate FG is. The semiconductor film 60a is made, for example, of polysilicon into which a p-type impurity (boron, for example) is doped.

The electrode film 70 (first electrode film), which contains a metal, is provided on the semiconductor film 60a. The electrode film 70 has a metal compound film 72 having conductivity and a metal film 71 containing a metal. The metal compound film 72 is provided on the semiconductor film 60a, and the metal film 71 is provided on the metal compound film 72.

The metal compound film 72 is made, for example, of a tungsten nitride. The metal film 71 is made, for example, of tungsten.

Using a film containing a metal to form each of the control gates CG allows reduction in the resistance of the control gate CG.

The control gate CG and the floating gate FG in each of the memory cells MC are capacitively coupled to each other via the interlayer insulating film 40.

The plurality of memory cells MC are laid out in a matrix on the substrate 10. Each of the memory cells MC includes one floating gate FG surrounded by an insulator.

The floating gate FG is covered with an insulator and is not electrically connected to any portion. As a result, even when electric power is turned off, electrons stored in the floating gate FG do not leak therefrom or no electrons newly enter the floating gate FG. That is, the semiconductor memory device of the embodiment is a nonvolatile semiconductor memory device capable of holding data with no electric power supplied.

The gate insulating film 20 (fifth insulating film) is provided on the third channels 12c of the selection transistors ST. A fourth semiconductor film 30a is provided on the gate insulating film 20. The fourth semiconductor film 30a is made, for example, of a p-type semiconductor. The fourth semiconductor film 30a is made, for example, of polysilicon into which a p-type impurity (boron, for example) is doped.

The interlayer insulating film 40 (sixth insulating film) is provided on the fourth semiconductor film 30a. The semiconductor film 60a (fifth semiconductor film) is provided on the interlayer insulating film 40, as in the case of the memory cells MC.

An electrode film 70 (first electrode film) is provided on the semiconductor film 60a. The electrode film 70 has a metal compound film 72 having conductivity and a metal film 71 containing a metal. The metal compound film 72 is provided on the semiconductor film 60a, and the metal film 71 is provided on the metal compound film 72.

The metal compound film 72 is made, for example, of a tungsten nitride. The metal film 71 is made, for example, of tungsten.

A recess 51, which passes through the interlayer insulating film 40 and reaches the fourth semiconductor film 30a, is provided in the drain-side selection gate SGD, and the semiconductor film 60a is provided in the recess 51. The semiconductor film 60a is thus in contact with the fourth semiconductor film 30a.

The electrode film 70, the semiconductor film 60a, and the semiconductor film 30a in each of the selection transistors ST are electrically connected to each other and form the gate electrode of the selection transistor ST.

FIG. 2B is a schematic cross-sectional view of the high-voltage peripheral transistor Trh taken along the line B-B′ in FIG. 1B.

As shown in FIG. 2B, a second channel 12b is provided on the surface of the substrate 10 and in the position where the high-voltage peripheral transistor Trh is present. The gate insulating film 20 (third insulating film) is provided on the second channel 12b. A second semiconductor film 30b is provided on the gate insulating film 20. The second semiconductor film 30b is made, for example, of an n-type (first-conductivity-type) semiconductor. The second semiconductor film 30b is made, for example, of polysilicon into which an n-type impurity (phosphorous, for example) is doped.

The interlayer insulating film 40 (fourth insulating film) is provided on the second semiconductor film 30b. The electrode film 70 (second electrode film) is provided on the interlayer insulating film 40. The electrode film 70 may, for example, have the metal compound film 72 and the metal film 71, as described above.

A recess 52, which passes through the interlayer insulating film 40 and reaches the second semiconductor film 30b, is provided in the high-voltage peripheral transistor Trh. A third semiconductor film 60b is provided on the side surface of the recess 52. The third semiconductor film 60b is so provided that it is in contact with the upper surface of the second semiconductor film 30b and the side surface of the interlayer insulating film 40. The third semiconductor film 60b is made of the same p-type semiconductor material as that of the semiconductor film 60a described above.

The electrode film 70 is provided as an integrated part on the interlayer insulating film 40, the second semiconductor film 30b, and the third semiconductor film 60b. The electrode film 70 covers the third semiconductor film 60b.

The metal compound film 72 (WN film) of the electrode film 70 is in contact with the second semiconductor film 30b at the bottom of the recess 52. The metal film (W film) 71 is provided on the metal compound film 72.

The electrode film 70 and the semiconductor film 30b of the high-voltage peripheral transistor Trh are electrically connected to each other and form the gate electrode of the high-voltage peripheral transistor Trh.

FIG. 2C is a schematic cross-sectional view of the low-voltage peripheral transistor Trl taken along the line C-C′ in FIG. 1B. The low-voltage peripheral transistor Trl has a structure in which a recess 53 is narrower than the recess in the structure of the high-voltage peripheral transistor Trh.

A second channel 12b is provided on the surface of the substrate 10 and in the position where the low-voltage peripheral transistor Trl is present, as shown in FIG. 2C. The gate insulating film 20 is provided on the second channel 12b. The gate insulating film 20 in the low-voltage peripheral transistor Trl is thinner than the gate insulating film 20 in the high-voltage peripheral transistor Trh. The second semiconductor film 30b is provided on the gate insulating film 20.

The interlayer insulating film 40 is provided on the second semiconductor film 30b. The electrode film 70 is provided on the interlayer insulating film 40. The electrode film 70 may, for example, have the metal compound film 72 and the metal film 71, as described above.

The recess 53, which passes through the interlayer insulating film 40 and reaches the second semiconductor film 30b, is provided in the low-voltage peripheral transistor Trl. The third semiconductor film 60b is provided on the side surface of the recess 53. The third semiconductor film 60b is so provided that it is in contact with the upper surface of the second semiconductor film 30b and the side surface of the interlayer insulating film 40.

The electrode film 70 is provided as an integrated part on the interlayer insulating film 40, the second semiconductor film 30b, and the third semiconductor film 60b. The electrode film 70 covers the third semiconductor film 60b.

The metal compound film (WN film) 72 of the electrode film 70 is in contact with the second semiconductor film 30b at the bottom of the recess 53. The area where the electrode film 70 is in contact with the second semiconductor film 30b in the low-voltage peripheral transistor Trl is smaller than the area where the electrode film 70 is in contact with the second semiconductor film 30b in the high-voltage peripheral transistor Trh.

The electrode film 70 and the semiconductor film 30b in the low-voltage peripheral transistor Trl are electrically connected to each other and form the gate electrode of the low-voltage peripheral transistor Trl.

FIG. 2D is a schematic cross-sectional view of a passive element portion Rc in the peripheral circuit (hereinafter referred to as passive element portion) taken along the line D-D′ in FIG. 1B. The passive element portion Rc is provided in a region which is outside the memory cell region 100 and where no peripheral transistor is formed. The passive element portion Rc, for example, includes a capacitive element having an insulating film made, for example, of an IPD (interpoly dielectric).

The passive element portion Rc is provided with no recess, unlike the structures of the selection transistors ST and the peripheral transistors Trh, Trl described above.

The gate insulating film 20 is provided on the substrate 10, as shown in FIG. 2D. The second semiconductor film 30b is provided on the gate insulating film 20.

The interlayer insulating film 40 is provided on the second semiconductor film 30b. The third semiconductor film 60b is provided on the interlayer insulating film 40. The electrode film 70 is provided on the third semiconductor film 60b. The electrode film 70 may, for example, have the metal compound film 72 and the metal film 71, as described above.

For example, as the gate electrode of a NAND flash memory, a polyside (such as tungsten silicide+polysilicon, cobalt silicide+polysilicon, and nickel silicide+polysilicon) or a polymetal (tungsten+polysilicon) is, for example, used to reduce the resistance of the gate electrode.

In a polymetal structure, a Schottky junction based, for example, on the difference in work function between interlayer contact surfaces is formed. The Schottky junction increases interlayer interface resistance in some cases. Further, a carrier dopant (impurity) in the polysilicon condenses, resulting in an increase in the interlayer interface resistance in some cases. Moreover, a non-carrier dopant lowers the rate of activation of the carrier dopant, resulting in an increase in the resistance in some cases.

According to the embodiment, the electrode film 70 in each of the peripheral transistors Trh and Trl provided in a peripheral circuit region 110 is in contact with the upper surface of the interlayer insulating film 40 via no third semiconductor film 60b. When the third semiconductor film 60b is etched back, the third semiconductor film 60b is caused to recede until the upper surface of the interlayer insulating film 40 is exposed, as will be described later. In this case, the semiconductor film 60b may be formed to have a film thickness smaller than that in a structure in which the semiconductor film 60b is left on the interlayer insulating film 40. As a result, the width of the third semiconductor film 60b formed on the side surface of each of the recesses 52 and 53 can be reduced.

The area of the electrode film 70 where the electrode film 70 is in contact with the second semiconductor film 30b can therefore be increased in each of the peripheral transistors Trh and Trl as compared with the structure of the selection transistors ST in which the semiconductor film 60a is provided between the electrode film 70 and the interlayer insulating film 40. As a result, the interface resistance between the electrode film 70 and the second semiconductor film 30b can be reduced.

Further, the area where the electrode film 70 is in contact with the third semiconductor film 60b can be reduced. As a result, bonding between the electrode film 70 (nitrogen in tungsten nitride film, for example) and the impurity contained in the third semiconductor film 60b (boron, for example) can be suppressed, whereby the resistance of the electrode film 70 can be reduced.

The electrode film 70 has the metal compound film 72 and the metal film 71. That is, the metal compound film 72 is provided between the metal film 71 and the second semiconductor film 30b. The contact resistance between the second semiconductor film 30b and the metal compound film 72 is lower than the contact resistance between the second semiconductor film 30b and the metal film 71. As a result, the contact resistance between the electrode film 70 and the second semiconductor film 30b can be further reduced.

In each of the peripheral transistors Trh and Trl, the small size of the third semiconductor film 60b allows the amount of the impurity contained in the p-type third semiconductor film 60b (boron, for example) and diffused into the n-type second semiconductor film 30b, in addition to the advantageous effects described above. As a result, an increase in the interface resistance between the metal compound film 72 and the second semiconductor film 30b in each of the peripheral transistors Trh and Trl can be suppressed.

Further, according to the embodiment, the conductivity type of the third semiconductor film 60b differs from the conductivity type of the second semiconductor film 30b but is the same as the conductivity type of the semiconductor film 60a. As a result, in a manufacturing process described later, the third semiconductor film 60b and the semiconductor film 60a can be simultaneously formed, whereby the number of manufacturing processes can be reduced and variation in characteristics of the semiconductor memory device can be reduced.

As described above, according to the semiconductor memory device of the embodiment, the characteristics of the device including those of the control circuit can be improved.

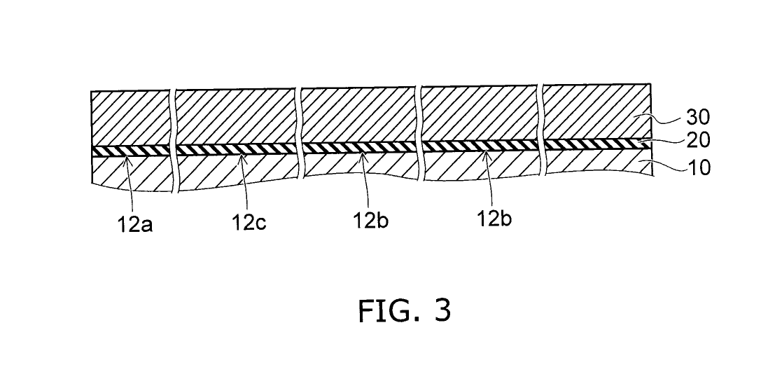

A method for manufacturing the semiconductor memory device of the embodiment will next be described with reference FIG. 3 to FIG. 7D.

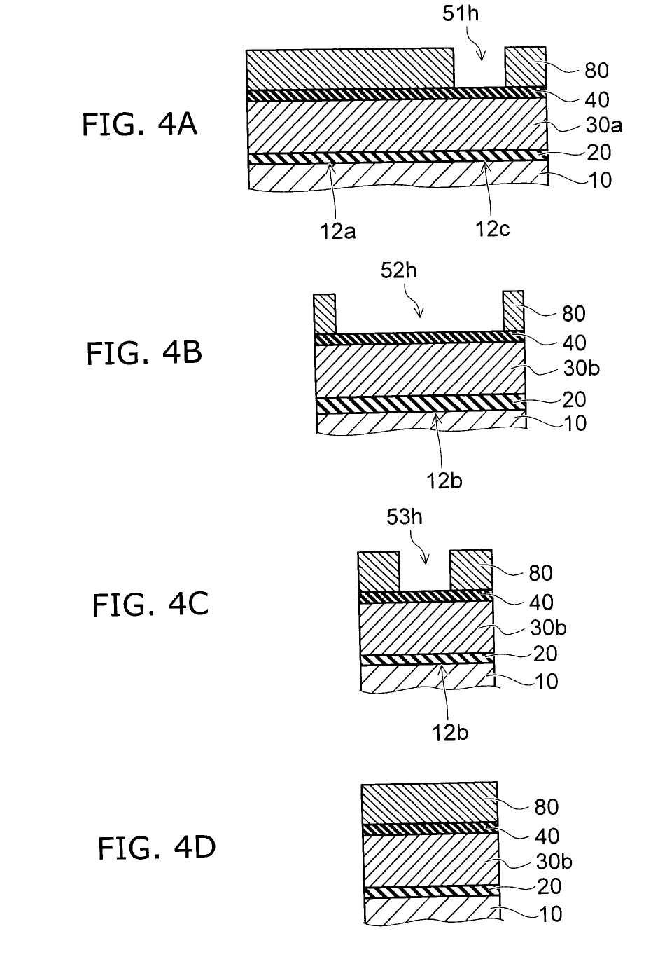

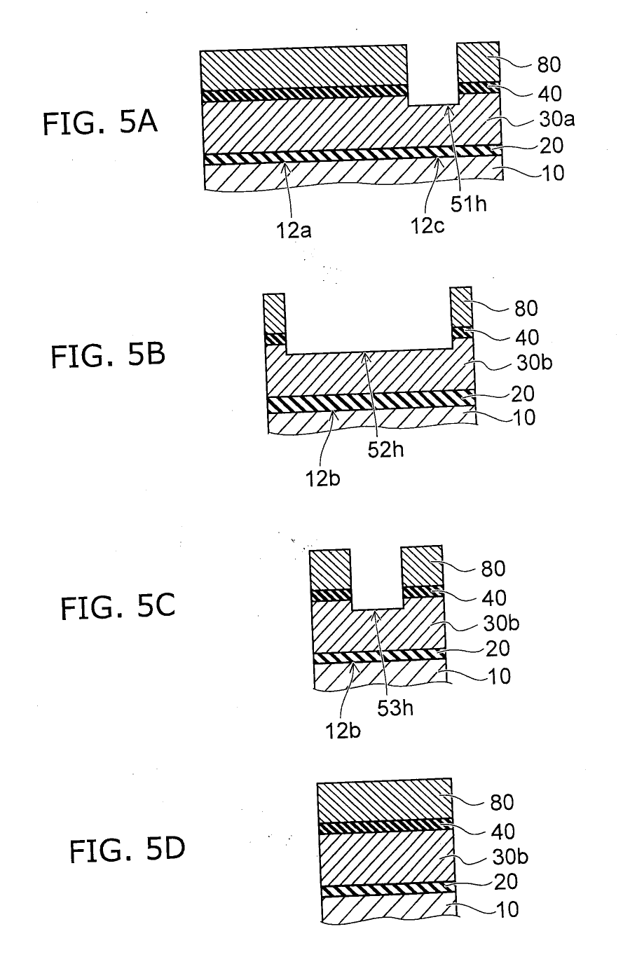

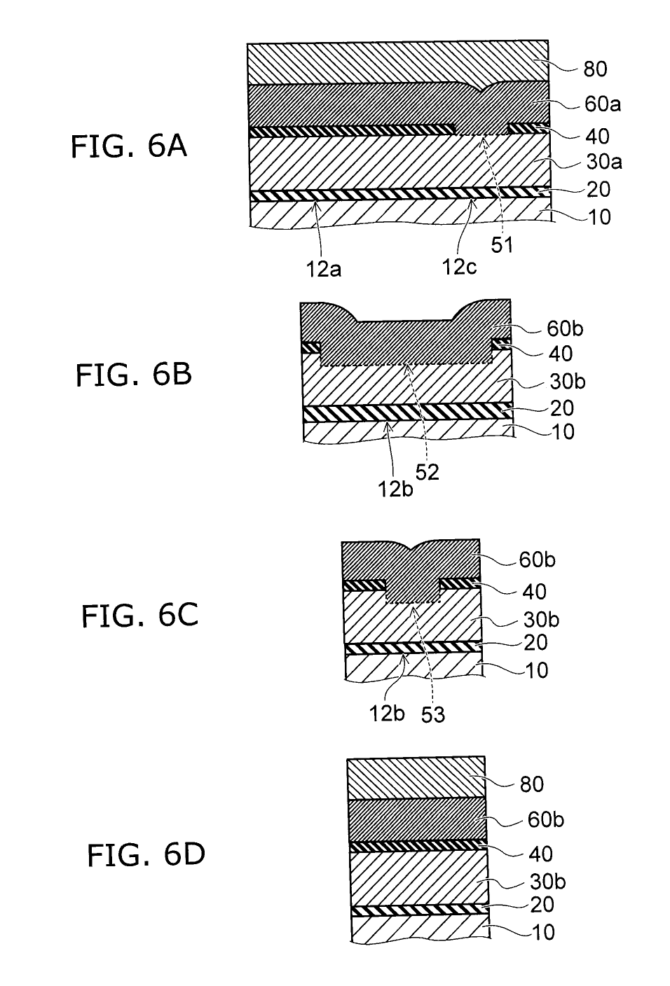

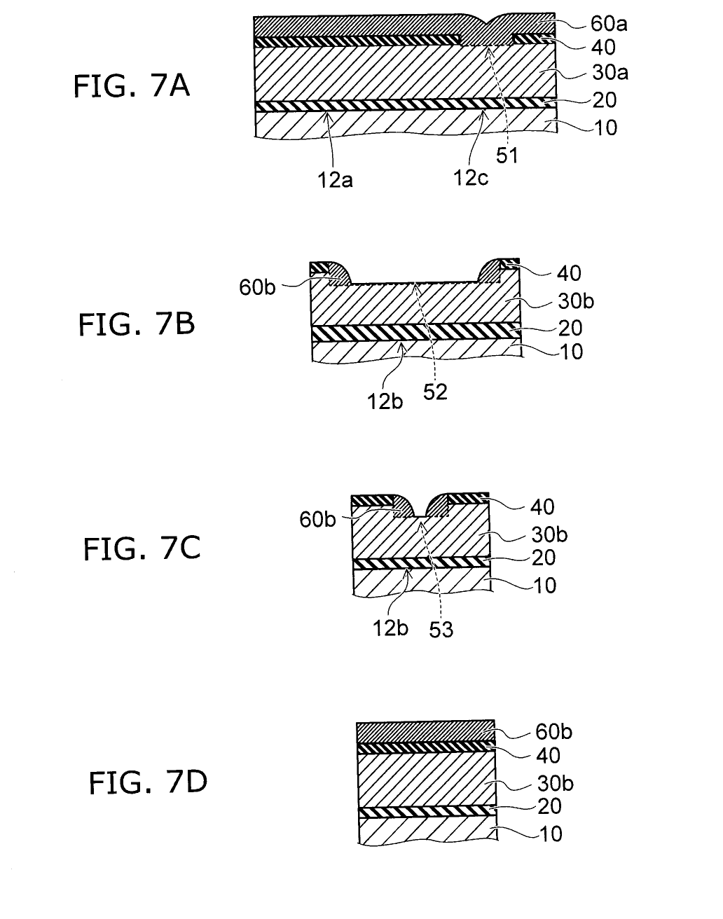

FIG. 3 is a schematic cross-sectional view of the method for manufacturing the semiconductor memory device of the embodiment. FIG. 4A, FIG. 5A, FIG. 6A, and FIG. 7A are schematic cross-sectional views of a method for manufacturing the memory cells MC and the selection transistors ST. FIG. 4B, FIG. 5B, FIG. 6B, and FIG. 7B are schematic cross-sectional views of a method for manufacturing the high-voltage peripheral transistor Trh. FIG. 4C, FIG. 5C, FIG. 6C, and FIG. 7C are schematic cross-sectional views of a method for manufacturing the low-voltage peripheral transistor Trl. FIG. 4D, FIG. 5D, FIG. 6D, and FIG. 7D are schematic cross-sectional views of a method for manufacturing the passive element portion Rc.

The channels 12a, 12b, and 12c are formed on the surface of the substrate 10, as shown in FIG. 3. The gate insulating film (first insulating film) 20 is formed on the channels 12a, 12b, and 12c. The memory cells MC, the selection transistors ST, the high-voltage peripheral transistor Trh, the low-voltage peripheral transistor Trl, and the passive element portion Rc are formed on the same substrate 10. The gate insulating film 20 formed as a gate insulating film of the high-voltage peripheral transistor Trh is thicker than the gate insulating film 20 formed as a gate insulating film of the low-voltage peripheral transistor Trl.

A semiconductor film 30 (first semiconductor film) is formed on the gate insulating film 20. The semiconductor film 30 is made, for example, of amorphous silicon into which an impurity is doped.

The semiconductor film 30a, which is the semiconductor film 30 to which a p-type impurity (boron, for example) is, for example, doped, is formed on the first channels 12a and the third channels 12c, as shown in FIG. 4A.

The semiconductor film 30b, which is the semiconductor film 30 to which an n-type impurity (phosphorous, for example) is, for example, doped, is formed on the substrate 10 and in the positions where the second channels 12b and the passive element portion Rc are present, as shown in FIG. 4B to FIG. 4D. The impurity doped to each of the semiconductor films 30a and 30b is arbitrarily selected, and an impurity having the same conductivity type may be doped to the semiconductor films 30a and 30b.

The interlayer insulating film 40 (second insulating film, IPD) is formed on the semiconductor films 30a and 30b. A resist 80 is formed on the interlayer insulating film 40. Thereafter, part of the resist 80 is removed, for example, by using a PEP (photo engraving process) method to form openings 51h, 52h, and 53h.

Instead of forming the resist 80 described above, a silicon nitride film may be formed, for example, by using a film formation method using hexachlorodisilane (HCD/Si₂Cl₆) gas and ammonia (NH₃) as raw material gases (HCD-SiN), or a polysilicon film may be formed.

The openings 51h, 52h, and 53h pass through the interlayer insulating film 40 and reach the semiconductor films 30a and 30b, as shown in FIG. 5B to FIG. 5D. The openings 51h, 52h, and 53h are formed, for example, by using an RIE (reactive ion etching) method. The opening 52h formed in FIG. 5B is wider than the opening 53h formed in FIG. 5C.

The semiconductor films 30a and 30b are exposed at the bottoms of the openings 51h, 52h, and 53h.

The resist 80 formed on the interlayer insulating film 40 is then removed. The resist 80 is removed, for example, by using ashing (asher).

The semiconductor films 60a and 60b (second semiconductor films) are formed on the interlayer insulating film 40 and in the openings 51h, 52h, and 53h, as shown in FIG. 6A to FIG. 6D. The semiconductor films 60a and 60b are buried in the openings 51h, 52h, and 53h. The recesses 51, 52, and 53 are thus formed. The semiconductor films 60a and 60b are in contact with the semiconductor films 30a and 30b through the recesses 51, 52, and 53.

The semiconductor films 60a and 60b are made, for example, of amorphous silicon into which a p-type impurity (boron, for example) is doped. Each of the semiconductor films 60a and 60b has a thickness of, for example, 20 nm or less.

The resist 80 is formed on the semiconductor films 60a and 60b and in portions other than the portions where the channels 12b are formed on the substrate 10, as shown in FIG. 6A and FIG. 6D. That is, the resist 80 is formed on the semiconductor films 60a and 60b and in portions where the memory cells MC, the selection transistors ST, and the passive element portion Rc are formed.

The resist 80 on the semiconductor film 60b and in portions where the channels 12b are formed on the substrate 10 is removed, for example, by using the PEP method, as shown in FIG. 6B and FIG. 6C. That is, the resist 80 on the semiconductor film 60b and in portions where the high-voltage peripheral transistor Trh and the low-voltage peripheral transistor Trl are formed.

The semiconductor film 60b in portions where the resist 80 has not been formed is then removed. The removal of the semiconductor film 60b is performed, for example, by using the RIE method.

The removal of the semiconductor film 60b exposes the upper surface of the interlayer insulating film 40, as shown in FIG. 7B and FIG. 7C. Further, the semiconductor film 30b is exposed at the bottom of each of the recesses 52 and 53 (second openings).

In this case, the semiconductor film 60a and 60b may be formed to have a film thickness smaller than that in a structure in which the semiconductor film 60b is left on the interlayer insulating film 40. The surface area of the semiconductor film 30b exposed at the bottom of each of the recesses 52 and 53 can therefore be increased.

The semiconductor film 60b formed on the sidewall of each of the recesses 52 and 53 is not removed but is left and in contact with the side surface of the interlayer insulating film 40 and the upper surface of the semiconductor film 30b. Instead, for example, a small portion of the semiconductor film 60b may be left on the sidewall of each of the recesses 52 and 53.

In contrast, the semiconductor film 60b formed in the recess 51 (first opening) and on the interlayer insulating film 40 around the recess 51 is not removed but is left.

The resist 80 formed on the semiconductor films 60a and 60b is then removed, as shown in FIG. 7A and FIG. 7D.

A heat treatment is then, for example, performed to crystallize the amorphous silicon. The electrode film 70 is then formed on the upper surface of each of the portions described above, as shown in FIG. 2A to FIG. 2D, and the memory cells MC, the selection transistors ST, and the peripheral transistors Trh and Trl are so processed that the gate electrodes and other portions thereof are formed. The semiconductor memory device of the embodiment is thus formed.

According to the embodiment, the electrode film 70 is formed on the interlayer insulating film 40 in each of the peripheral transistors Trh and Trl with no interposed semiconductor film 60b. As a result, the nitrogen or any other substance contained in the electrode film 70 and the boron or any other substance contained in the semiconductor film 60b are not bonded to each other on the interlayer insulating film 40, whereby an increase in the interface resistance can be suppressed. Further, since the size of the semiconductor film 60b left on the semiconductor film 30b can be reduced, the area where the electrode film 70 is in contact with the semiconductor film 30b can be increased accordingly, whereby the contact resistance can be reduced.

Further, the area where the electrode film 70 is in contact with the semiconductor film 60b in each of the peripheral transistors Trh and Trl can be reduced. Bonding between the electrode film 70 and the impurity contained in the semiconductor film 60b can therefore be suppressed, whereby the resistance of the electrode film 70 can be lowered.

Further, a multilayer film having the metal compound film 72 and the metal film 71 can be formed as the electrode film 70. That is, the metal compound film 72 is formed between the metal film 71 and the semiconductor film 30b. The contact resistance between the electrode film 70 and the semiconductor film 30b can therefore be further lowered.

In addition to the above, the amount of the impurity contained in the semiconductor film 60b and diffused into the semiconductor film 30b can be reduced. As a result, an increase in the interface resistance between the metal compound film 72 and the second semiconductor film 30b in each of the peripheral transistors Trh, Trl can be suppressed.

According to the embodiment, the portions described above (memory cells MC, selection transistors ST, and peripheral transistors Trh and Trl) can be manufactured all together. The number of manufacturing processes can therefore be reduced, whereby variation in the characteristics of the semiconductor memory device can be reduced.

As described above, according to the semiconductor memory device of the embodiment, the characteristics of the device including those of the control circuit can be improved.

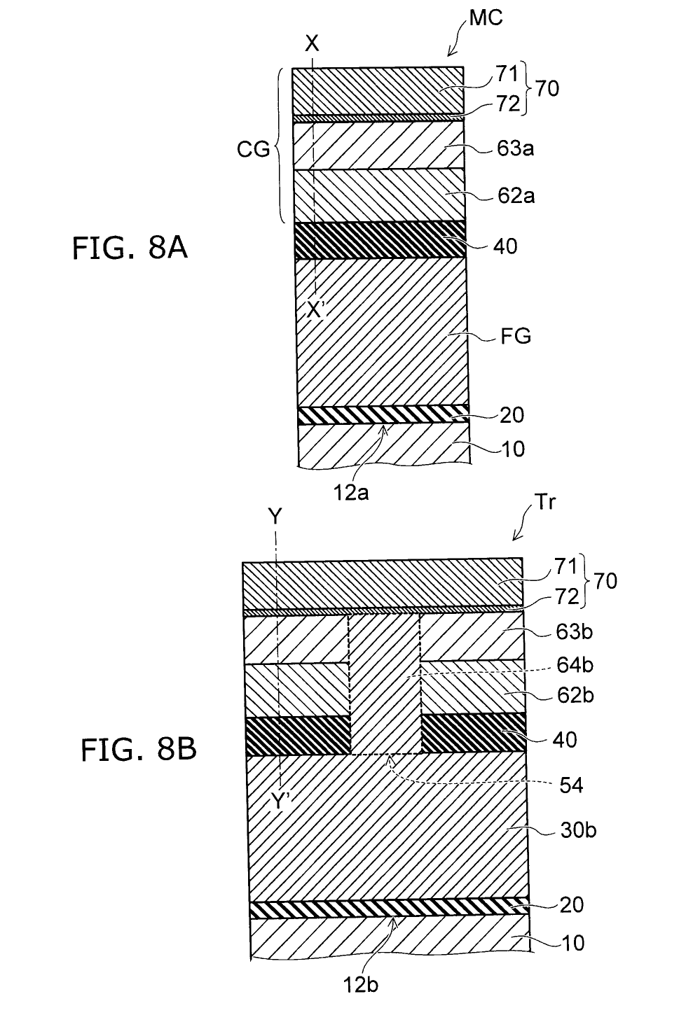

FIG. 8A and FIG. 8B are schematic cross-sectional views of a semiconductor memory device of another embodiment. FIG. 8A is a schematic cross-sectional view of a memory cell MC.

A first channel 12a is provided on the surface of a substrate 10, as shown in FIG. 8A. A gate insulating film 20 (first insulating film) is provided on the first channel 12a. The gate insulating film 20 is made, for example, of a silicon oxide film.

A floating gate FG (charge storage film) is provided on the gate insulating film 20. The floating gate FG is made, for example, of polysilicon into which a p-type impurity (boron, for example) is doped.

An interlayer insulating film 40 (second insulating film) is provided on the floating gate FG. The interlayer insulating film 40 is made, for example, of a material having relative permittivity higher than that of the gate insulating film 20. The interlayer insulating film 40 is formed, for example, of an ONO film, an NONON film, or an insulating film having a high dielectric characteristic, such as an oxynitride film having an intermediate characteristic between the ONO film and the NONON film.

A control gate CG is provided on the interlayer insulating film 40. The control gate CG has a first semiconductor film 62a, a second semiconductor film 63a, and an electrode film 70.

The first semiconductor film 62a is provided on the interlayer insulating film 40. The second semiconductor film 63a is provided on the first semiconductor film 62a. Each of the first semiconductor film 62a and the second semiconductor film 63a is made of a p-type semiconductor.

The first semiconductor film 62a is made of a material different from the material of the second semiconductor film 63a. The first semiconductor film 62a is made of a material having a p-type impurity activation rate higher than that of the second semiconductor film 63a. The first semiconductor film 62a is made, for example, of polysilicon germanium, and the second semiconductor film 63a is made, for example, of polysilicon. A p-type impurity (boron, for example) is doped to each of the materials of the first and second semiconductor films 62a, 63a. The impurity activation concentration in the first semiconductor film 62a is higher than the impurity activation concentration in the second semiconductor film 63a. The first semiconductor film 62a may instead be made, for example, of polysilicon containing indium.

The electrode film 70 is provided on the second semiconductor film 63a. The electrode film 70 has a metal compound film 72 and a metal film 71. The metal compound film 72 is provided on the second semiconductor film 63a, and the metal film 71 is provided on the metal compound film 72.

The metal compound film 72 is formed, for example, of a tungsten nitride film, and the metal film 71 is made, for example, of tungsten.

FIG. 8B is a schematic cross-sectional view of a peripheral transistor Tr in a peripheral circuit.

The peripheral transistor Tr is provided on the same substrate 10 on which the memory cell MC is provided, as shown in FIG. 8B.

A second channel 12b is provided on the surface of the substrate 10. The gate insulating film 20 (third insulating film) is provided on the second channel 12b. A first gate film 30b (third semiconductor film) is provided on the gate insulating film 20. The first gate film 30b is made, for example, of an n-type semiconductor. The first gate film 30b is made, for example, of polysilicon into which an n-type impurity (phosphorous, for example) is doped.

The interlayer insulating film 40 (fourth insulating film) is provided on the first gate film 30b. A second lower-layer gate film 62b (fourth semiconductor film) is provided on the interlayer insulating film 40. A second upper-layer gate film 63b (fifth semiconductor film) is provided on the second lower-layer gate film 62b.

The second lower-layer gate film 62b contains a material different from a material contained in the second upper-layer gate film 63b. Each of the second lower-layer gate film 62b and the second upper-layer gate film 63b is made of an n-type semiconductor, as the first gate film 30b is.

The second lower-layer gate film 62b is made, for example, of the same polysilicon germanium as that of the second semiconductor film 62a, and the second upper-layer gate film 63b is made, for example, of the same polysilicon as that of the third semiconductor film 63a. A p-type impurity (boron, for example) and an n-type impurity (phosphorous, for example) are doped into the materials of the second lower-layer gate film 62b and the second upper-layer gate film 63b. The activation concentration of the n-type impurity (phosphorous, for example) contained in the second lower-layer gate film 62b and the second upper-layer gate film 63b is higher than the activation concentration of the p-type impurity (boron, for example) contained therein. As a result, each of the second lower-layer gate film 62b and the second upper-layer gate film 63b is made of an n-type semiconductor. The second lower-layer gate film 62b may instead be made, for example, of polysilicon containing indium.

A recess 54, which passes through the second upper-layer gate film 63b to the interlayer insulating film 40, is provided in the peripheral transistor Tr. A semiconductor film 64b (sixth semiconductor film) is provided in the recess 54.

The semiconductor film 64b is buried in the recess 54. The lower surface of the semiconductor film 64b is in contact with the upper surface of the first gate film 30b. The semiconductor film 64b is in contact with the interlayer insulating film 40, the second lower-layer gate film 62b, and the second upper-layer gate film 63b.

The electrode film 70 is provided on the second upper-layer gate film 63b and the semiconductor film 64b. The electrode film 70 has the metal compound film 72 and the metal film 71. The metal compound film 72 is provided on the second upper-layer gate film 63b and the semiconductor film 64b, and the metal film 71 is provided on the metal compound film 72.

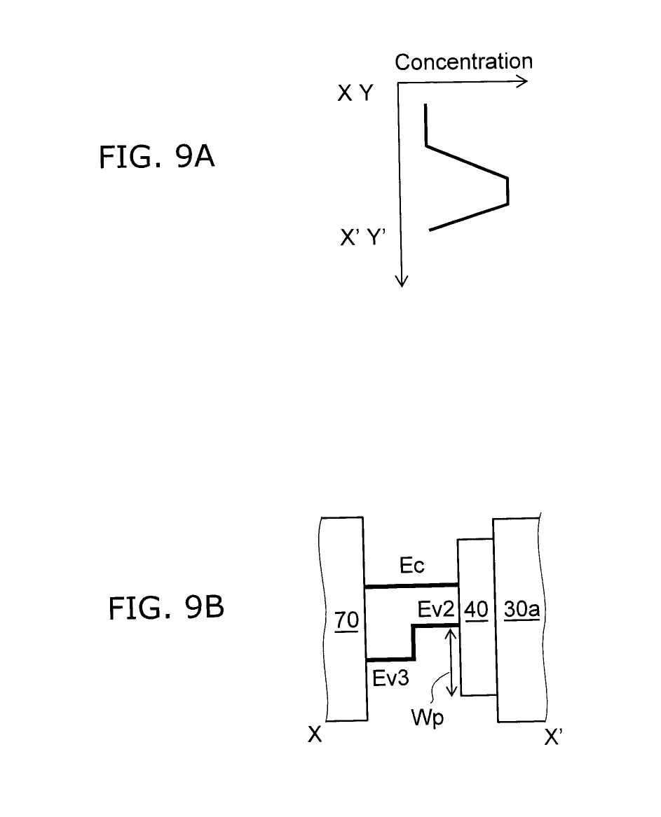

FIG. 9A is a concentration profile diagram of the impurity (boron) contained in the structure in the X-X′ cross section in FIG. 8A and in the Y-Y′ cross section in FIG. 8B. The vertical axis corresponds to positions along the lines X-X′ and Y-Y′, and the horizontal axis represents the concentration of boron.

The concentration of boron in a position closer to X′ and Y′ is higher than the concentration of boron in a position closer to X and Y, as shown in FIG. 9A. That is, the concentration of boron in the first semiconductor film 62a is higher than the concentration of boron in the second semiconductor film 63a in the memory cell MC. Further, the concentration of boron in the second upper-layer gate film 63b is lower than the concentration of boron in the second lower-layer gate film 62b in the peripheral transistor Tr.

FIG. 9B is an energy band diagram in the X-X′ cross section in FIG. 8A. The vertical axis corresponds to positions along the line X-X′. The upper solid line represents a conduction band end, and the lower solid line represents a valence band end.

The difference between a valence band end Ev2 of the first semiconductor film 62a and a conduction band end Ec is smaller than the difference between a valence band end Ev3 of the second semiconductor film 63a and the conduction band end Ec, as shown in FIG. 9B. As a result, a potential well Wp for holes is formed in the first semiconductor film 62a and in a position in the vicinity of the interlayer insulating film 40.

According to the embodiment, the first semiconductor film 62a and the second semiconductor film 63a are provided between the interlayer insulating film 40 and the electrode film 70 in the memory cell MC. In this configuration, the activation concentrations of boron contained in the first semiconductor film 62a and the second semiconductor film 63a can be so set that the concentration in the first semiconductor film 62a is higher than the concentration in the second semiconductor film 63a.

The second lower-layer gate film 62b and the second upper-layer gate film 63b are provided between the interlayer insulating film 40 and the electrode film 70 in the peripheral transistor Tr, as in the memory cell MC. In this configuration, the activation concentrations of boron contained in the second lower-layer gate film 62b and the second upper-layer gate film 63b can be so set that the concentration in the second upper-layer gate film 63b is lower than the concentration in the second lower-layer gate film 62b.

The reason for this is that the boron doped into the first semiconductor film 62a (second lower-layer gate film 62b) is less likely to be diffused than the boron doped into the second semiconductor film 63a (second upper-layer gate film 63b), and that the activation rate of the boron doped into the first semiconductor film 62a (second lower-layer gate film 62b) is higher than the activation rate of the boron doped into the second semiconductor film 63a (second upper-layer gate film 63b).

As a result, when data in the memory cell MC is deleted, the amount of depletion in the polysilicon gate electrode in the vicinity of the interface between the first semiconductor film 62a and the interlayer insulating film 40 can be suppressed, whereby the data deletion characteristic of the memory cell MC can be improved, and the resistance of the interface between the second upper-layer gate film 63b and the electrode film 70 in the peripheral transistor Tr can be lowered. The operation speed of the peripheral circuit including the peripheral transistor Tr can thus be improved.

Further, a multilayer film having the metal compound film 72 and the metal film 71 can be provided as the electrode film 70, as in the embodiment described above. That is, the metal compound film 72 is formed between the metal film 71 and the second upper-layer gate film 63b. The contact resistance between the electrode film 70 and the second upper-layer gate film 63b can therefore be further lowered.

In addition to the above, the potential well Wp for holes is provided between the first semiconductor film 62a and the interlayer insulating film 40 in the memory cell MC.

For example, to write data to the memory cell MC, a positive voltage is applied to the control gate CG, and electrons are injected from the substrate 10 into the floating gate FG via the gate insulating film 20. In this process, as the voltage applied to the control gate CG increases, the electrons from the floating gate FG pass through the interlayer insulating film 40 and flow into the control gate CG, and saturation of data writing to the memory cell MC occurs. In this phenomenon, the data writing saturation characteristic of the memory cell MC is degraded when hole current flows from the control gate CG through the interlayer insulating film 40 into the floating gate FG.

In contrast, according to the embodiment, in which the potential well Wp for the holes is provided, the hole current flowing from the control gate CG through the interlayer insulating film 40 into the floating gate FG can be suppressed, whereby the data writing saturation characteristic of the memory cell MC can be improved.

As described above, according to the semiconductor memory device of the embodiment, the characteristics of the device including those of the peripheral circuit can be improved.

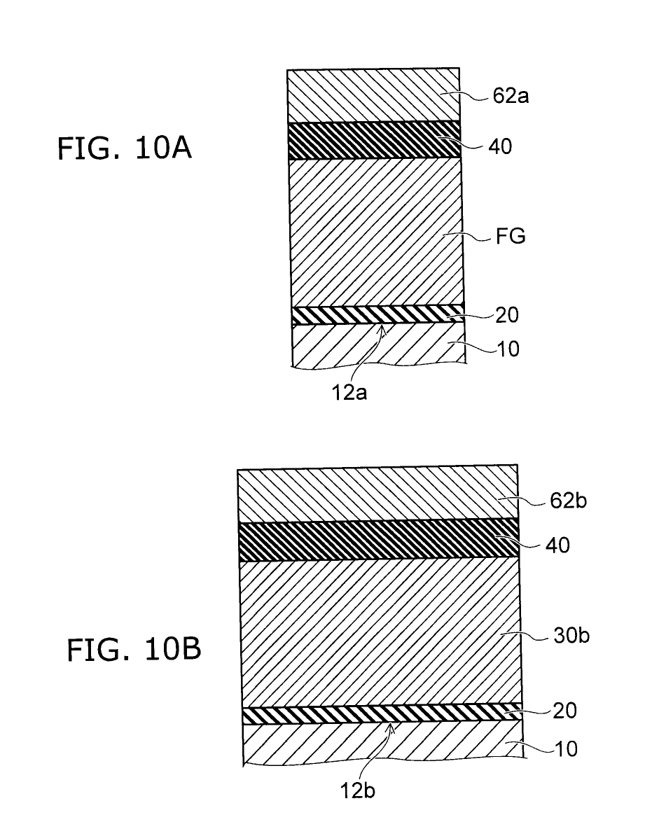

A method for manufacturing a semiconductor memory device of another embodiment will be described with reference to FIG. 10A to FIG. 12B.

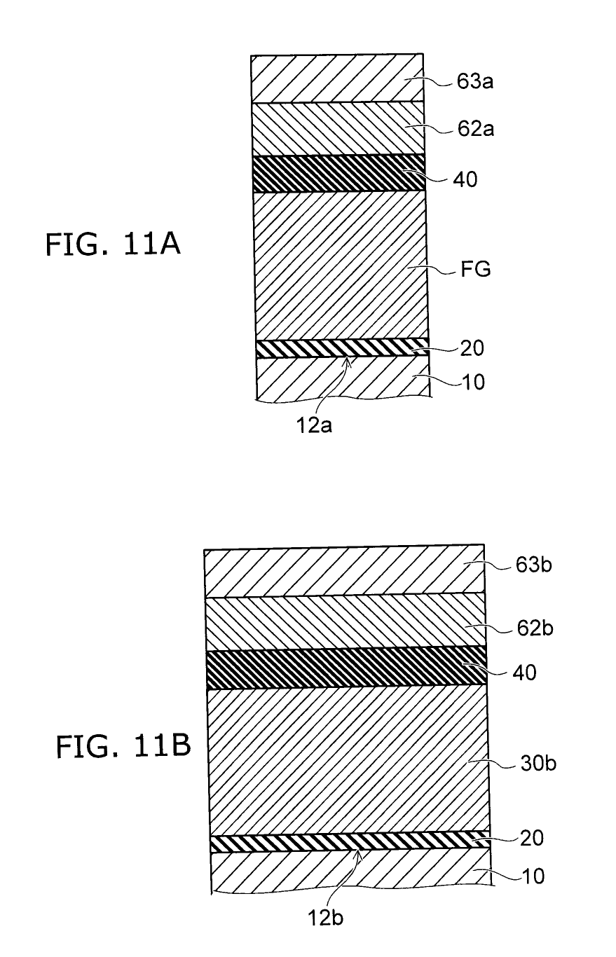

FIG. 10A and FIG. 11A are schematic cross-sectional views of a method for manufacturing a memory cell MC, and FIG. 10B and FIG. 11B to FIG. 12B are cross-sectional views of a method for manufacturing a peripheral transistor Tr.

A first channel 12a and a second channels 12b are formed on the surface of a substrate 10, as shown in FIG. 3, as in the embodiment described above. A gate insulating film 20 (first insulating film) is formed on each of the first channel 12a and the second channels 12b. The memory cell MC and the peripheral transistor Tr are formed on the same substrate 10. In the embodiment, no description will be made of the processes of manufacturing the selection transistors ST and the passive element portion Rc.

A semiconductor film 30 (first semiconductor film) is formed on the gate insulating film 20. The semiconductor film 30 is made, for example, of amorphous silicon into which an impurity is doped.

A floating gate FG made of amorphous silicon into which an impurity has been doped is formed on the gate insulating film 20 on the first channel 12a, as shown in FIG. 10A. A p-type impurity (boron, for example) is, for example, doped into the floating gate FG.

Further, a first gate film 30b made of amorphous silicon into which an impurity has been doped is formed on the gate insulating film 20 on the second channel 12b, as shown in FIG. 10B. An n-type impurity (phosphorus, for example) is, for example, doped into the first gate film 30b.

An interlayer insulating film 40 (second insulating film) is formed on the floating gate FG and the first gate film 30b, as shown in FIG. 10A and FIG. 10B. Semiconductor films 62a and 62b (second semiconductor films) are formed on the interlayer insulating film 40. The semiconductor film 62a is formed on the floating gate FG, and the semiconductor film 62b is formed on the first gate film 30b. The semiconductor films 62a and 62b are made, for example, of amorphous silicon germanium into which a p-type impurity (boron, for example) is doped.

Semiconductor films 63a and 63b (third semiconductor films) are formed on the semiconductor films 62a and 62b, as shown in FIG. 11A and FIG. 11B. The semiconductor film 63a is formed on the semiconductor film 62a, and the semiconductor film 63b is formed on the semiconductor film 62b.

The semiconductor films 63a and 63b contain materials different from those of the semiconductor films 62a and 62b. The second semiconductor films 63a and 63b are made, for example, of amorphous silicon into which a p-type impurity is doped, as the semiconductor films 62a and 62b are.

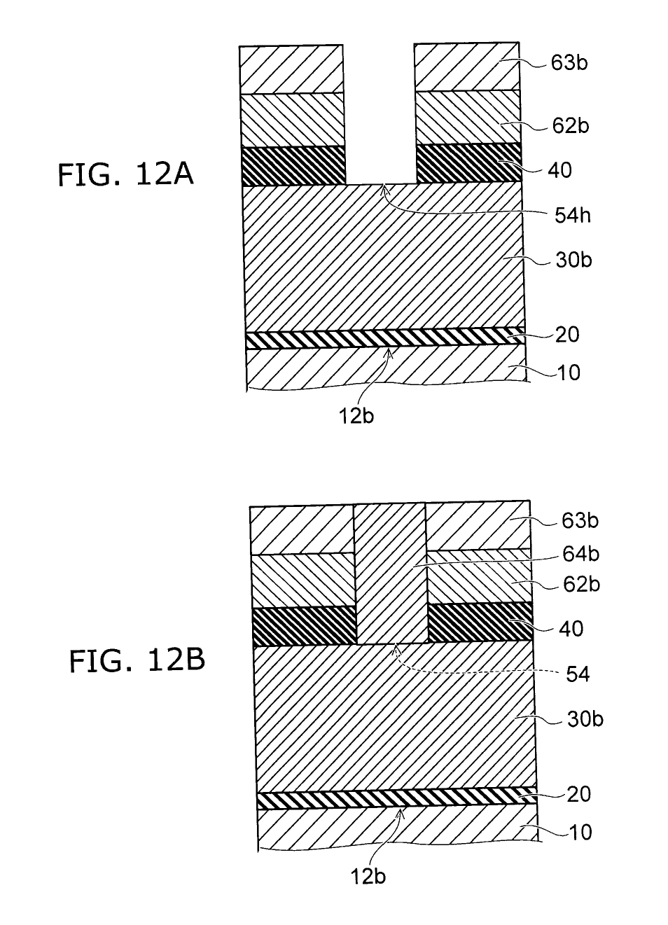

An opening 54h, which passes through the semiconductor films 63b and 62b and the interlayer insulating film 40 formed on the second channel 12b and reaches the first gate film 30b, is formed, as shown in FIG. 12A. As a method for forming the opening 54h, an RIE process using a mask that is not shown is, for example, used. The first gate film 30b is exposed at the bottom of the opening 54h.

A semiconductor film 64b (fourth semiconductor film) is subsequently formed in the opening 54h, as shown in FIG. 12B. The semiconductor film 64b is buried in the opening 54h. A recess 54 is thus formed.

The semiconductor film 64b is in contact with the upper surface of the first gate film 30b. The semiconductor film 64b is in contact with the interlayer insulating film 40 and the semiconductor films 62b and 63b.

The semiconductor film 64b is made, for example, of amorphous silicon into which no impurity is doped. The p-type impurity doped into the semiconductor films 62b and 63b is slightly doped into the semiconductor film 64b due, for example, to heat generated in a manufacturing process.

An n-type impurity (such as phosphorous, arsenic) is then doped into each of the semiconductor films 62b, 63b, and 64b by using ion injection or any other method. The concentration of the n-type impurity having been doped into each of the semiconductor films 62b, 63b, and 64b is higher than the concentration of the p-type impurity having been doped into each of the semiconductor films 62b, 63b, and 64b. A second lower-layer gate film 62b and a second upper-layer gate film 63b are thus formed.

A heat treatment is then, for example, performed to crystallize the amorphous silicon contained in each of the floating gate FG, the first gate film 30b, the second lower-layer gate film 62b, the second upper-layer gate film 63b, and the semiconductor films 62a, 63a, and 64b.

Thereafter, a metal compound film 72 is formed on each of the second semiconductor film 63a, the second upper-layer gate film 63b, and the semiconductor film 64b, and the metal film 71 is formed on the metal compound film 72, as shown in FIG. 8A and FIG. 8B. The memory cell MC and the peripheral transistor Tr are so processed that the gate electrodes and other portions thereof are formed. The semiconductor memory device of the embodiment is thus formed.

According to the embodiment, the semiconductor film 62a is formed on the interlayer insulating film 40 in the memory cell MC, and the semiconductor film 63a is formed on the semiconductor film 62a. In this process, the activation concentrations of boron contained in the semiconductor film 62a and the semiconductor film 63a can be so set that the concentration in the semiconductor film 62a is higher than the concentration in the semiconductor film 63a.

On the other hand, the second lower-layer gate film 62b is formed on the interlayer insulating film 40 in the peripheral transistor Tr, and the second upper-layer gate film 63b is formed on the second lower-layer gate film 62b, as in the case of the memory cell MC. In this process, the activation concentrations of boron contained in the second lower-layer gate film 62b and the second upper-layer gate film 63b can be so set that the concentration in the second lower-layer gate film 62b is higher than the concentration in the second upper-layer gate film 63b.

As a result, when data in the memory cell MC is deleted, the amount of depletion in the polysilicon gate electrode in the vicinity of the interface between the semiconductor film 62a and the interlayer insulating film 40 can be suppressed, whereby the data deletion characteristic of the memory cell MC can be improved, and the resistance of the interface between the second upper-layer gate film 63b and the electrode film 70 in the peripheral transistor Tr can be lowered. The operation speed of the peripheral circuit including the peripheral transistor Tr can thus be improved.

Further, a multilayer film having the metal compound film 72 and the metal film 71 can be formed as the electrode film 70, as in the embodiment described above. That is, the metal compound film 72 is provided between the metal film 71 and the second upper-layer gate film 63b. The contact resistance between the electrode film 70 and the second upper-layer gate film 63b can therefore be further lowered.

In addition to the above, the semiconductor film 62a is made of polysilicon germanium, and the semiconductor film 63a is made of polysilicon. As a result, the potential well Wp for holes is formed between the semiconductor film 62a and the interlayer insulating film 40, whereby the writing saturation characteristic of the memory cell MC can be improved.

According to the embodiment, the portions described above (memory cell MC, peripheral transistors Tr) can be manufactured all together. The number of manufacturing steps can therefore be reduced, whereby variation in the characteristics of the semiconductor memory device can be reduced.

As described above, according to the semiconductor memory device of the embodiment, the characteristics of the device including those of the peripheral circuit can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a memory cell; and
a peripheral transistor,
the memory cell including
a first channel,
a first insulating film provided on the first channel,
a charge storage film provided on the first insulating film,
a second insulating film provided on the charge storage film,
a first semiconductor film provided on the second insulating film, and
a first electrode film provided on the first semiconductor film and including a metal, and
the peripheral transistor including
a second channel,
a third insulating film provided on the second channel,
a second semiconductor film provided on the third insulating film,
a fourth insulating film provided on the second semiconductor film,
a third semiconductor film provided on the second semiconductor film and a side surface of the fourth insulating film, and
a second electrode film provided on the fourth insulating film without the third insulating film between the second electrode film and the fourth insulating film, provided on the second semiconductor film in contact with the second semiconductor film, and including a metal.

2. The device according to claim 1, wherein the third semiconductor film is a silicon film into which boron is doped.

3. The device according to claim 1, wherein the second semiconductor film is a first conductivity type, and the third semiconductor film is a second conductivity type.

4. The device according to claim 1, wherein the second electrode film includes
a metal compound film provided in contact with the second semiconductor film, the third semiconductor film, and the fourth insulating film, and
a metal film provided on the metal compound film.

5. The device according to claim 4, wherein the metal compound film includes tungsten nitride, and the metal film includes tungsten.

6. The device according to claim 1, further comprising a selection transistor,
the selection transistor including
a third channel,
a fifth insulating film provided on the third channel,
a fourth semiconductor film provided on the fifth insulating film,
a sixth insulating film provided on the fourth semiconductor film,
a fifth semiconductor film provided on the sixth insulating film and provided on the fourth semiconductor film in contact with the fourth semiconductor film, and
a third electrode film provided on the fifth semiconductor film and containing a metal.

7. The device according to claim 6, wherein the second semiconductor film in the peripheral transistor is a first conductivity type, and the third semiconductor film in the peripheral transistor, the fourth semiconductor film and the fifth semiconductor film in the selection transistor are a second conductivity type.

8. The device according to claim 1, wherein the memory cell and the peripheral transistor are provided on a same substrate.

9. The device according to claim 6, wherein the memory cell, the peripheral transistor, and the selection transistor are provided on a same substrate.

10. A semiconductor memory device comprising:
a memory cell; and
a peripheral transistor,
the memory cell including
a first channel,
a first insulating film provided on the first channel,
a charge storage film provided on the first insulating film,
a second insulating film provided on the charge storage film,
a first semiconductor film provided on the second insulating film,
a second semiconductor film provided on the first semiconductor film, including a material different from a material of the first semiconductor film, and having an impurity concentration lower than an impurity concentration of the first semiconductor film, and
a first electrode film provided on the second semiconductor film and containing a metal, and
the peripheral transistor including
a second channel,
a third insulating film provided on the second channel,
a third semiconductor film provided on the third insulating film,
a fourth insulating film provided on the third semiconductor film,
a fourth semiconductor film provided on the fourth insulating film,
a fifth semiconductor film provided on the fourth semiconductor film and containing a material different from a material of the fourth semiconductor film,
a second electrode film provided on the fifth semiconductor film and including a metal, and
a sixth semiconductor film piercing through the fifth semiconductor film, the fourth semiconductor film, and the fourth insulating film and provided in contact with the second electrode film and the third semiconductor film.

11. The device according to claim 10, wherein an impurity activation rate in the first semiconductor film is higher than an impurity activation rate in the second semiconductor film, and
an impurity activation rate in the fourth semiconductor film is higher than an impurity activation rate in the fifth semiconductor film.

12. The device according to claim 10, wherein each of the first semiconductor film, the second semiconductor film, the fourth semiconductor film, and the fifth semiconductor film includes silicon and boron.

13. The device according to claim 12, wherein each of the first semiconductor film and the fourth semiconductor film includes at least one of germanium and indium.

14. The device according to claim 10, wherein the first electrode film has
a first metal compound film provided on the second semiconductor film, and
a first metal film provided on the first metal compound film, and
the second electrode film has
a second metal compound film provided on the fifth semiconductor film and the sixth semiconductor film, and
a second metal film provided on the second metal compound film.

15. The device according to claim 14, wherein each of the first metal compound film and the second metal compound film includes tungsten nitride, and each of the first metal film and the second metal film includes tungsten.

16. A method for manufacturing a semiconductor memory device, the method comprising:
forming a first insulating film on a surface of a substrate;
forming a first semiconductor film on the first insulating film;
forming a second insulating film on the first semiconductor film;
forming a first opening and a second opening that pass through the second insulating film and reach the first semiconductor film;
forming a second semiconductor film in the first opening, in the second opening, and on the second insulating film;
exposing an upper surface of the first semiconductor film at a bottom of the second opening and an upper surface of the second insulating film around the second opening with the second semiconductor film left in the first opening and on the second insulating film around the first opening; and
forming an electrode film including a metal on the second semiconductor film on the first opening, on the second semiconductor film around the first opening, on the first semiconductor film at the bottom of the second opening, and on the second insulating film around the second opening.

17. The method according to claim 16, wherein the second semiconductor film in the second opening and on the second insulating film around the second opening is etched back, with a mask layer formed in the first opening and on the second semiconductor film on the second insulating film around the first opening, to expose an upper surface of the first semiconductor film at the bottom of the second opening and an upper surface of the second insulating film around the second opening.

18. The method according to claim 16, wherein the second semiconductor film is left on a sidewall of the second opening.

19. The method according to claim 16, wherein the first semiconductor film below the second opening is a first conductivity type, the second semiconductor film is a second conductivity type, and the first semiconductor film below the first opening is the second conductivity type.

20. The method according to claim 16,
wherein the forming of the electrode film includes
forming a metal compound film on the second semiconductor film, the second insulating film, and the first semiconductor film, and
forming a metal film on the metal compound film.
